(19) United States
(12) Patent Application Publication
(10) Pub. No.: US 2026/0189232 A1
(43) Pub. Date: Jul. 2, 2026

(54) LEVEL SHIFTER CIRCUIT

(71) Applicant: TEXAS INSTRUMENTS INCORPORATED, Dallas, TX (US)

(72) Inventors: Venkateswarlu RAMASWAMY T, Bangalore (IN); Padmanabh S PRABHU, Thiruvananthapuram (IN)

(21) Appl. No.: 19/004,555

(22) Filed: Dec. 30, 2024

(51) Int. Cl. H03K 19/0185; H02M 1/00; H03K 3/033; H03K 3/037

(52) U.S. Cl. CPC H03K 19/018521; H02M 1/0029; H03K 3/033; H03K 3/037

(57) ABSTRACT

A circuit includes a latch, a first variable resistor, a second variable resistor, a slew detector, and a conductor configured to provide a power supply voltage. The latch has a first latch input, a second latch input, a first latch output, and a second latch output. The first variable resistor has a first terminal coupled to the conductor, a second terminal coupled to the first latch input, a first control input, and a second control input coupled to the first latch output. The second variable resistor has a first terminal coupled to the conductor, a second terminal coupled to the second latch input, a third control input, and a fourth control input coupled to the second latch output. The slew detector is coupled to the conductor. The slew detector has an output coupled to the first control input and the third control input.

### BACKGROUND

Electronic systems often have circuits that are powered by different power supply voltages or that require different signal levels to activate circuit components. In such systems level shifter circuits (level shifters) are used to translate signals from one voltage level to another. For example, a level shifter may be used to translate a signal from a lower voltage to a higher voltage, or to translate a signal from a higher voltage to a lower voltage.

### SUMMARY

In one example, a circuit includes a latch, a first variable resistor, a second variable resistor, a slew detector, and a conductor configured to provide a power supply voltage. The latch has a first latch input, a second latch input, a first latch output, and a second latch output. The first variable resistor has a first terminal coupled to the conductor, a second terminal coupled to the first latch input, a first control input, and a second control input coupled to the first latch output. The second variable resistor has a first terminal coupled to the conductor, a second terminal coupled to the second latch input, a third control input, and a fourth control input coupled to the second latch output. The slew detector is coupled to the conductor. The slew detector has an output coupled to the first control input and the third control input.

In another example, a circuit includes a latch, a slew detector, a first variable resistor, and a second variable resistor. The latch has a set input and a reset input. The slew detector has a terminal coupled to a power terminal, and an output. The slew detector is configured to provide at the output a slew sense signal based on a rate of change of voltage on the power terminal. The first variable resistor is coupled between the power terminal and the set input. The first variable resistor has a control input coupled to the output of the slew detector. The first variable resistor is configured to change a resistance of the first variable resistor based on the slew sense signal. The second variable resistor is coupled between the power terminal and the reset input. The second variable resistor has a control input coupled to the output of the slew detector. The second variable resistor is configured to change a resistance of the second variable resistor based on the slew sense signal.

In a further example, a switching converter includes a high-side transistor and a driver. The high-side transistor has a first terminal coupled to an input voltage terminal, a second terminal coupled to a switching terminal, and a control terminal. The driver has an output coupled to the control terminal of the high-side transistor. The driver includes a level shifter having a first output coupled to the output of the driver, and a second output. The level shifter includes a latch, a slew detector, a first variable resistor, and a second variable resistor. The latch has a first latch output coupled to the output of the level shifter, a second latch output, a set input, and a reset input. The latch is configured to provide a first latch output signal at the first latch output, and provide a second latch output signal at the second latch output. The slew detector has a terminal coupled to a power terminal, and an output. The slew detector is configured to provide, at the output of the slew detector, a slew sense signal based on a rate of change of voltage on the power terminal. The first variable resistor is coupled between the power terminal and the set input. The first variable resistor has a first control input coupled to the output of the slew detector and a second control input coupled to the first output of the latch. The first variable resistor is configured to change a resistance of the first variable resistor based on the slew sense signal and the first latch output signal. The second variable resistor is coupled between the power terminal and the reset input. The second variable resistor has a third control input coupled to the output of the slew detector and a fourth control input coupled to the second output of the latch. The second variable resistor is configured to change a resistance of the second variable resistor based on the slew sense signal and the second latch output signal.

### BRIEF DESCRIPTION OF THE DRAWINGS

FIG. 1 is a schematic diagram of an example level shifter that includes a slew rate detector and variable resistors.

FIG. 2 is a block diagram of a switching converter, in an example, that includes the level shifter of FIG. 1.

FIG. 3 is a graph of signals in the switching converter of FIG. 2.

### DETAILED DESCRIPTION

A level shifter circuit may be used in a switching converter to shift a lower voltage transistor control signal to a higher voltage that is suitable for driving a high-side transistor of the switching converter. The level shifter circuit may include high-voltage transistors that shift the control signal to a higher output voltage. The high-voltage transistors may have a large parasitic capacitance between the drain of the transistor and the substrate of an integrated circuit on which the transistors are formed. If the reference voltage used by the level shifter circuit changes rapidly, transients may be generated at the outputs of the level shifter circuit if the parasitic capacitance is not discharged at the same rate as the change in reference voltage.

The level shifter circuit described herein includes variable resistance pull-up resistors, and modulates the resistance of the pull-up resistors based on a slew rate of a reference voltage sensed by a slew rate detection circuit. The slew rate detection circuit includes a high-voltage transistor of the same type used elsewhere in the level shifter circuit to provide a capacitance that closely matches the parasitic capacitance that should be discharged to prevent output transients. Accordingly, the slew rate detector can be implemented without use of a high voltage capacitor, which reduces overall circuit size.

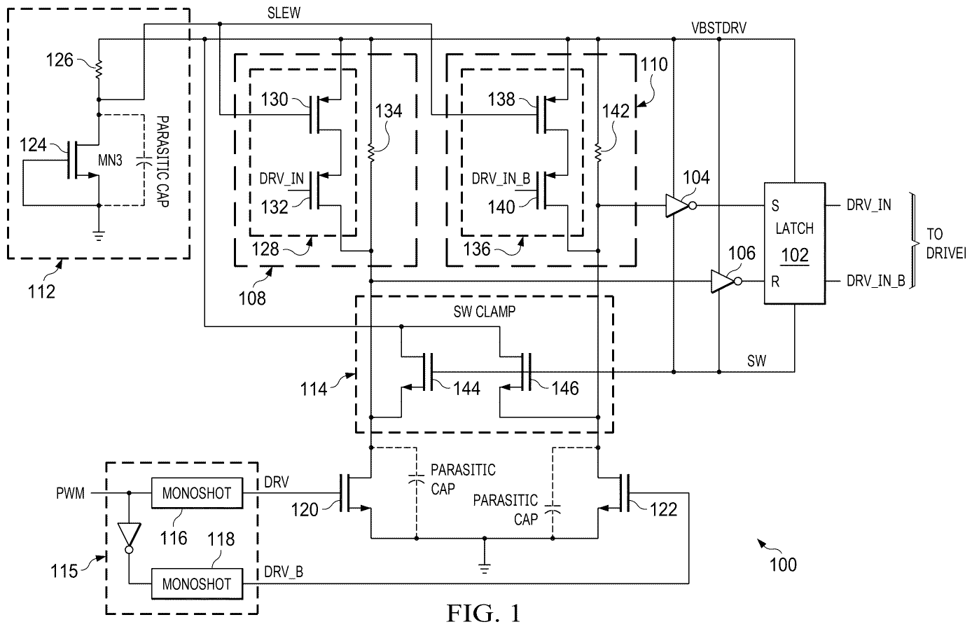

FIG. 1 is a schematic diagram of an example level shifter 100. The level shifter 100 includes a latch 102, inverters 104 and 106, variable resistors 108 and 110, a slew detector 112, a clamp circuit 114, a pulse generator 115, monostable one-shots 116 and 118, and transistors 120 and transistor 122. The pulse generator 115 includes monostable one-shot 116 and the monostable one-shot 118 with inputs that are coupled to a control signal circuit, such as a pulse width modulation circuit. The monostable one-shot 116 and the monostable one-shot 118 generate pulses on the edges of the control signal (PWM). The monostable one-shot 116 generates a pulse responsive to the rising edge of PWM, and the monostable one-shot 118 generates a pulse responsive to the falling edge of the PWM. The pulses provided by the monostable one-shot 116 and the monostable one-shot 118 trigger the latch 102 to generate the output signals DRV_IN and DRV_IN_B.

The latch 102 has a voltage terminal coupled to a boost voltage terminal (also referred to as a boost voltage conductor) (VBSTDRV) and a reference terminal coupled to a reference voltage terminal (SW). The levels of DRV_IN and DRV_IN_B are established by the voltages at VBSTDRV and SW. The voltage at VBSTDRV may be provided as the voltage at SW plus an offset voltage (e.g., 5 volts). The latch 102 has output terminals, at which DRV_IN and DRV_IN_B are provided. The output terminals of the latch 102 may be coupled to inputs of a buffer circuit or other circuit. The latch 102 has a set input and a reset input. The set input is coupled to an output of the inverter 104, and the reset input is coupled to an output of the inverter 106.

The transistor 120 and the transistor 122 are controlled by the signals DRV and DRV_B provided by the monostable one-shot 116 and the monostable one-shot 118. The transistor 120 and the transistor 122 may be n-channel field effect transistors (NFETs). The transistor 120 has a control terminal (e.g., gate) coupled to the pulse output of the monostable one-shot 116, a first terminal (e.g., drain) coupled to an input of the inverter 106, and second terminal (e.g., source) coupled to a reference voltage terminal (e.g., a ground terminal). The transistor 122 has a control terminal (e.g., gate) coupled to the pulse output of the monostable one-shot 118, a first terminal (e.g., drain) coupled to an input of the inverter 104, and a second terminal (e.g. source) coupled to the second terminal of the transistor 120.

Parasitic capacitance between the first terminal of the transistor 120 and the ground terminal, and between the first terminal of the transistor 122 and the ground terminal, must be charged and discharged at the same rate as the change in voltage on SW or undesirable transients may be generated at the output so the latch 102. In an integrated circuit, the parasitic capacitance of the transistors 120 and 122 may be formed between the substrate of the integrated circuit and an n-type buried layer of the integrated circuit. The variable resistor 108, the variable resistor 110, and the slew detector 112 enable fast charging and discharging of the parasitic capacitance of the transistor 120 and the transistor 122 while improving the power efficiency of the level shifter 100.

The slew detector 112 generates an output signal (SLEW) that represents the rate of change of voltage on SW (the slew rate of the voltage on SW and VBSTDRV). The output of the slew detector 112 is coupled to the variable resistor 108 and the variable resistor 110. Applying SLEW to the variable resistor 108 and the variable resistor 110 changes the resistance of the variable resistor 108 and the variable resistor 110 such that the resistances of the variable resistor 108 and variable resistor 110 are reduced if the slew rate of the voltage on SW is high. Accordingly, the variable resistor 108, the variable resistor 110, and the slew detector 112 allow the parasitic capacitance of the transistor 120 and the transistor 122 to be charged or discharged based on the slew rate of the voltage on SW.

The slew detector 112 includes a transistor 124 and a resistor 126. The transistor 124 may be an NFET that is a replica of the transistor 120 and the transistor 122. The transistor 124 has a first terminal (e.g., drain) coupled to the resistor 126, a second terminal (e.g., source) coupled to the ground terminal, and a control terminal (e.g., gate) coupled to the ground terminal. The resistor 126 has a first terminal coupled to the first terminal of the transistor 124, and a second terminal coupled to VBSTDRV. The first terminal of the resistor 126 serves as the output of the slew detector 112. The parasitic capacitance of the transistor 124 and the resistor 126 are coupled as a low-pass filter to generate SLEW.

The variable resistor 108 has a first terminal coupled to VBSTDRV, a second terminal coupled the input of the inverter 106 and the first terminal of the transistor 120, a first control terminal coupled to the output of the slew detector 112, and a second control terminal coupled to the first output of the latch 102. The variable resistor 108 includes a switch 128 and a resistor 134. The switch 128 is coupled in parallel with the resistor 134, and includes a transistor 130, and a transistor 132. The transistor 130 and the transistor 132 may be p-channel field effect transistors (PFETS). The switch 128 is controlled by SLEW and DRV_IN. The switch 128 has a first switch control input for receiving SLEW, and a second switch control input for receiving DRV_IN.

The resistor 134 is coupled between VBSTDRV and the input of the inverter 106. The resistor 134 has a first terminal coupled to VBSTDRV and a second terminal coupled to the input of the inverter 106 and the first terminal of the transistor 120. The transistor 130 and the transistor 132 are coupled in series between the first terminal of the resistor 134 and the second terminal of the resistor 134. The transistor 130 has a first terminal (e.g., source) coupled to VBSTDRV, a second terminal coupled to a first terminal (e.g., source) of the transistor 132, and a control terminal (e.g., gate) coupled to the first terminal of the resistor 126. The transistor 132 has a second terminal coupled to the input of the inverter 106 and the first terminal of the transistor 120, and a control terminal coupled to the first output of the latch 102. The transistor 132 is turned on by DRV_IN, and the transistor 130 is turned on by SLEW. Accordingly, if SLEW indicates that the slew rate of the voltage on SW is high, and DRV_IN is logic low, then the transistor 130 and the transistor 132 are turned on to reduce the resistance of the variable resistor 108. If DRV_IN is a logic high or SLEW indicates that the slew rate of the voltage on SW is not high, the resistance of the variable resistor 108 is the resistance of the resistor 134. Because the resistance of the variable resistor 108 changes based on SLEW, the resistance of the resistor 134 may be selected to be relatively high to improve power efficiency (e.g., reduce current flow through the resistor 134 to ground).

The variable resistor 110 has a first terminal coupled to VBSTDRV, a second terminal coupled the input of the inverter 104 and the first terminal of the transistor 122, a first control terminal coupled to the output of the slew detector 112, and a second control terminal coupled to the second output of the latch 102. The variable resistor 110 includes a switch 136 and a resistor 142. The switch 136 is coupled in parallel with the resistor 142, and includes a transistor 138, and a transistor 140. The transistor 138 and the transistor 140 may be p-channel field effect transistors (PFETS). The switch 136 is controlled by SLEW and DRV_IN_B. The switch 136 has a first switch control input for receiving SLEW, and a second switch control input for receiving DRV_IN_B.

The resistor 142 has a first terminal coupled to VBSTDRV and a second terminal coupled to the input of the inverter 104 and the first terminal of the transistor 122. The transistor 138 and the transistor 140 are coupled in series between the first terminal of the resistor 142 and the second terminal of the resistor 142. The transistor 138 has a first terminal (e.g., source) coupled to VBSTDRV, a second terminal coupled to a first terminal (e.g., source) of the transistor 140, and a control terminal (e.g., gate) coupled to the first terminal of the resistor 126. The transistor 140 has a second terminal coupled to the input of the inverter 104 and the first terminal of the transistor 122, and a control terminal coupled to the second output of the latch 102. The transistor 140 is turned on by DRV_IN_B, and the transistor 138 is turned on SLEW. Accordingly, if SLEW indicates that the slew rate of the voltage on SW is high, and DRV_IN_B is logic low, then the transistor 138 and the transistor 140 are turned on to reduce the resistance of the variable resistor 110. If DRV_IN_B is a logic high or SLEW indicates that the slew rate of the voltage on SW is not high, the resistance of the variable resistor 110 is the resistance of the resistor 142. Because the resistance of the variable resistor 110 changes based on slew, the resistance of the resistor 142 may be selected to be relatively high to improve power efficiency (e.g., reduce current flow through the resistor 142 to ground).

The clamp circuit 114 clamps the voltages at the inputs of the inverters 104 and 106 based on the voltage on SW. The clamp circuit 114 includes a transistor 144 and a transistor 146. The transistors 144 and 146 may be NFETs. The transistor 144 has a first terminal (e.g., drain) coupled to VBSTDRV, a second terminal (e.g., source) coupled to the input of the inverter106, and a control terminal (e.g., gate) coupled to SW. The transistor 146 has a first terminal (e.g., drain) coupled to the first terminal of the transistor 144, a second terminal (e.g., source) coupled to the input of the inverter 104, and a control terminal (e.g., gate) coupled to SW.

By using the variable resistors 108 and 110, and the slew detector 112, the level shifter 100 can overcome multiple issues present in other level shifter implementations. In one operational example, if the voltage on SW goes negative (e.g., −2 volts), then the voltage on VBSTDRV drops to −3 volts, and the transistors 120 and 122 operate in linear mode. The relatively large resistance of the resistors 134 and 142 is significantly higher than the on-resistance of the transistors 120 and 122 (the switches 128 and 136 are open) to ensure that the inverters 104 and 106 work properly. In another operational example, the voltage on SW rises with a fast slew rate, and the parasitic capacitors of the transistors 120 and 122 draw current through the variable resistors 108 and 110. Because the resistance of the variable resistors 108 and the 110 is reduced during high slew transitions on SW, the parasitic capacitance can be charged without a significant voltage drop at the inputs of the inverters 104 and 106 that might cause a transient at the output of the latch 102. In a level shifter lacking the variable resistors 108 and 110, and the slew detector 112, fixed resistor values may be selected to mitigate one problem or the other, but both issues cannot be resolved.

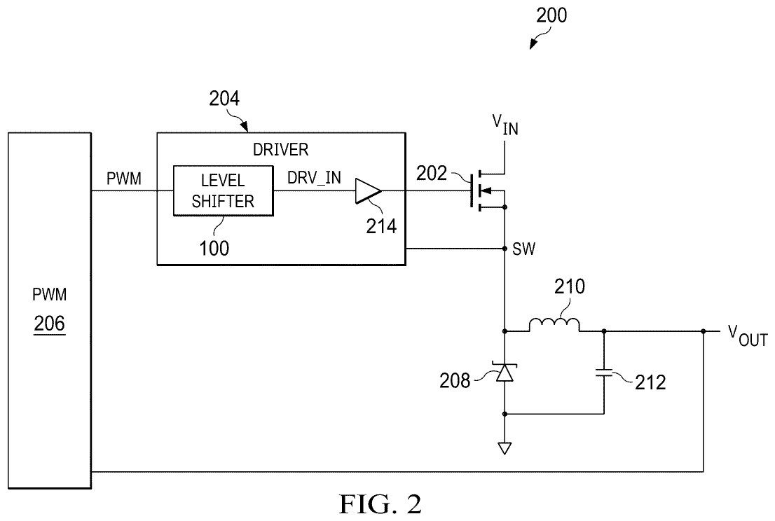

FIG. 2 is a block diagram of a switching converter 200. The switching converter 200 includes a high-side transistor 202, a driver 204, a pulse width modulator 206, a diode 208, an inductor 210, and a capacitor 212. The high-side transistor 202 may be an NFET. The high-side transistor 202 has first terminal (e.g., drain) coupled to an input voltage terminal (V_{IN}), a second terminal coupled to the switching terminal (SW), and a control terminal coupled to the driver 204. The diode 208 has a cathode coupled to SW and an anode coupled to a ground terminal. The inductor 210 has a first terminal coupled to SW, and a second terminal coupled to an output voltage terminal (V_{OUT}). The capacitor 212 is coupled between V_{OUT} and the ground terminal.

The driver 204 has an output coupled to the control terminal of the high-side transistor 202, an input coupled to SW, and an input coupled to the pulse width modulator 206. The driver 204 may apply the voltage at SW as a reference voltage, and generate VBSTDRV based on the voltage at SW (e.g., VBSTDRV is the voltage on SW plus 5 volts). The pulse width modulator 206 has an input coupled to V_{OUT}. The pulse width modulator 206 may generate the signal PWM based on the voltage at V_{OUT} to maintain a desired voltage at V_{OUT}. The driver 204 shifts the voltage of PWM to VBSTDRV to generate the signal DRV_IN. The driver 204 includes the level shifter 100, and a buffer 214. An input of the level shifter 100 is coupled to the output of the pulse width modulator 206 for receipt of PWM, and an output of the level shifter 100 is coupled to an input of the buffer 214 for providing DRV_IN to the buffer 214. An output of the buffer 214 is coupled to the control terminal of the high-side transistor 202. The buffer 214 buffers DRV_IN, and provides buffered DRV_IN to the high-side transistor 202 to control switching of the high-side transistor 202. The buffer 214 may control the drive current of buffered DRV_IN to control the switching of the high-side transistor 202.

The level shifter 100 receives PWM from the pulse width modulator 206 and shifts the voltage thereof to VBSTDRV to drive the high-side transistor 202. The slew detector 112 controls the resistance of the variable resistor 108 and the variable resistor 110 based on the slew rate of the voltage on SW. With the resistance of the variable resistor 108 and the variable resistor 110 changeable based on the slew rate of the voltage on SW, the parasitic capacitance of the transistor 120 and the transistor 122 can be charged and discharged based on the slew rate of the voltage on SW, and transients on DRV_IN can be reduced or avoided.

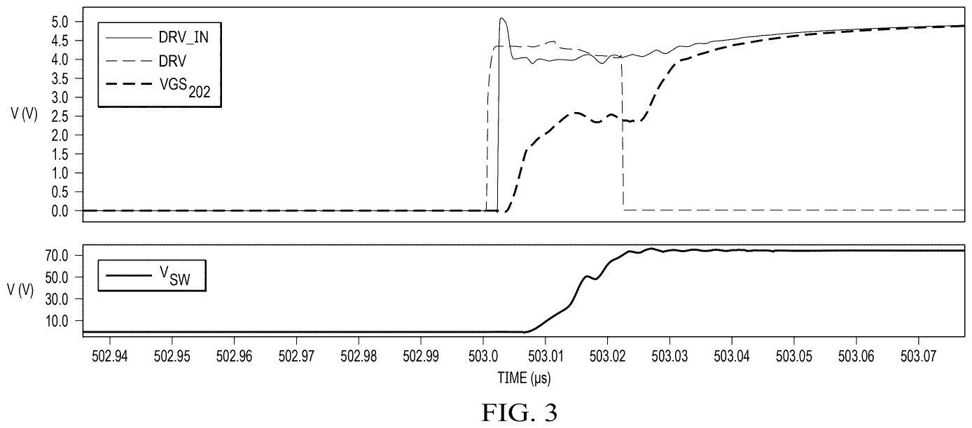

FIG. 3 is a graph of signals in the switching converter 200. FIG. 3 show DRV provided by the monostable one-shot 116, DRV_IN provided by the latch 102, the gate-to-source voltage (VGS₂₀₂) of the high-side transistor 202, and the voltage (V_{SW}) on SW. DRV_IN changes state shortly (e.g., less than 2 nanoseconds) after the leading edge of DRV. Responsive to DRV_IN, VGS₂₀₂ increases, and V_{SW} rises as the high-side transistor 202 turns on. Because the resistance of the variable resistor 108 and the variable resistor 110 is controlled based on the slew rate of V_{SW}, changing V_{SW} at a high slew rate does not cause a transient on DRV_IN.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET) ) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
a conductor configured to provide a power supply voltage;
a latch having a first latch input, a second latch input, a first latch output, and a second latch output;
a first variable resistor having a first terminal coupled to the conductor, a second terminal coupled to the first latch input, a first control input, and a second control input coupled to the first latch output;
a second variable resistor having a first terminal coupled to the conductor, a second terminal coupled to the second latch input, a third control input, and a fourth control input coupled to the second latch output; and
a slew detector coupled to the conductor, the slew detector having an output coupled to the first control input and the third control input.

2. The circuit of claim 1, wherein the slew detector includes:
a transistor having a control terminal, a first terminal coupled to a reference terminal and the control terminal, and a second terminal coupled to the output of the slew detector; and
a resistor coupled between the conductor and the second terminal of the transistor.

3. The circuit of claim 1, wherein the first variable resistor includes:
a resistor having a first terminal coupled to the conductor, and a second terminal coupled to the first latch input; and
a switch having a first terminal coupled to the conductor, a second terminal coupled to the first latch input, a first switch control input coupled to the first control input, and a second switch control input coupled to the second control input.

4. The circuit of claim 3, wherein the switch includes:
a first transistor having a first terminal coupled to the conductor, a second terminal, and a control terminal coupled to the first switch control input; and
a second transistor having a first terminal coupled to the second terminal of the first transistor, a second terminal coupled to the first latch input, and a control terminal coupled to the second switch control input.

5. The circuit of claim 1, wherein the second variable resistor includes:
a resistor having a first terminal coupled to the conductor, and a second terminal coupled to the second latch input; and
a switch having a first terminal coupled to the conductor, a second terminal coupled to the second latch input, a first switch control input coupled to the third control input, and a second switch control input coupled to the fourth control input.

6. The circuit of claim 5, wherein the switch includes:
a first transistor having a first terminal coupled to the conductor, a second terminal, and a control terminal coupled to the first switch control input; and
a second transistor having a first terminal coupled to the second terminal of the first transistor, a second terminal coupled to the second latch input, and a control terminal coupled to the second switch control input.

7. The circuit of claim 1, further comprising:
a pulse generator including:
a first monostable one-shot having a first pulse output;
a first transistor having a first terminal coupled to the first latch input, a second terminal coupled to a reference terminal, and a control terminal coupled to the first pulse output;
a second monostable one-shot having a second pulse output; and
a second transistor having a first terminal coupled to the second latch input, a second terminal coupled to the reference terminal, and a control terminal coupled to the second pulse output.

8. The circuit of claim 1, further comprising:
a first inverter having an input coupled to the second terminal of the first variable resistor, and an output coupled to the first latch input; and
a second inverter having an input coupled to the second terminal of the second variable resistor, and an output coupled to the second latch input.

9. The circuit of claim 8, further comprising:
a first transistor having a first terminal coupled to the conductor, a second terminal coupled to the second terminal of the first variable resistor; and control terminal coupled to a switching terminal; and
a second transistor having a first terminal coupled to the conductor, a second terminal coupled to the second terminal of the second variable resistor; and control terminal coupled to a switching terminal.

10. A circuit comprising:
a latch having a set input, and a reset input;
a slew detector having a terminal coupled to a power terminal, and an output, the slew detector configured to provide at the output a slew sense signal based on a rate of change of voltage on the power terminal;
a first variable resistor coupled between the power terminal and the set input, the first variable resistor having a control input coupled to the output of the slew detector, the first variable resistor configured to change a resistance of the first variable resistor based on the slew sense signal; and
a second variable resistor coupled between the power terminal and the reset input, the second variable resistor having a control input coupled to the output of the slew detector, the second variable resistor configured to change a resistance of the second variable resistor based on the slew sense signal.

11. The circuit of claim 10, wherein:
the control input of the first variable resistor is a first control input, and the first variable resistor has a second control input;
the control input of the second variable resistor is a third control input, and the second variable resistor has a fourth control input; and
the latch has a first latch output coupled to the second control input, and a second latch output coupled to the fourth control input.

12. The circuit of claim 10, wherein the slew detector includes:
a transistor having a control terminal, a first terminal coupled to a reference terminal and the control terminal, and a second terminal coupled to the output of the slew detector; and
a resistor coupled between the power terminal and the second terminal of the transistor.

13. The circuit of claim 11, wherein the first variable resistor includes:
a resistor coupled between the power terminal and the set input;
a first transistor having a first terminal coupled to the power terminal, a second terminal, and a control terminal coupled to the output of the slew detector; and
a second transistor having a first terminal coupled to the second terminal of the first transistor, a second terminal coupled to the set input, and a control terminal coupled to the first latch output.

14. The circuit of claim 11, wherein the second variable resistor includes:
a resistor coupled between the power terminal and the reset input;
a first transistor having a first terminal coupled to the power terminal, a second terminal, and a control terminal coupled to the output of the slew detector; and
a second transistor having a first terminal coupled to the second terminal of the first transistor, a second terminal coupled to the reset input, and a control terminal coupled to the second latch output.

15. The circuit of claim 11, further comprising:
a first monostable one-shot having a first pulse output, the first monostable one-shot configured to provide a pulse at the first pulse output; and
a second monostable one-shot having a second pulse output, the second monostable one-shot is configured to provide a pulse at the second pulse output;
a first transistor having a first terminal coupled to the set input, a second terminal coupled to a reference terminal, and a control terminal coupled to the second pulse output; and
a second transistor having a first terminal coupled to the reset input, a second terminal coupled to the reference terminal, and a control terminal coupled to the first pulse output.

16. A switching converter comprising:
a high-side transistor having a first terminal coupled to an input voltage terminal, a second terminal coupled to a switching terminal, and a control terminal;
a driver having an output coupled to the control terminal of the high-side transistor, the driver including a level shifter having a first output coupled to the output of the driver, and a second output, the level shifter including:
a latch having a first latch output coupled to the output of the level shifter, a second latch output, a set input and a reset input, the latch configured to provide a first latch output signal at the first latch output, and provide a second latch output signal at the second latch output;
a slew detector having a terminal coupled to a power terminal, and an output, the slew detector configured to provide, at the output of the slew detector, a slew sense signal based on a rate of change of voltage on the power terminal;
a first variable resistor coupled between the power terminal and the set input, the first variable resistor having a first control input coupled to the output of the slew detector and a second control input coupled to the first output of the latch, the first variable resistor configured to change a resistance of the first variable resistor based on the slew sense signal and the first latch output signal; and
a second variable resistor coupled between the power terminal and the reset input, the second variable resistor having a third control input coupled to the output of the slew detector and a fourth control input coupled to the second output of the latch, the second variable resistor configured to change a resistance of the second variable resistor based on the slew sense signal and the second latch output signal.

17. The switching converter of claim 16, wherein the slew detector includes:
a transistor having a control terminal, a first terminal coupled to a reference terminal and the control terminal, and a second terminal coupled to the output of the slew detector; and
a resistor coupled between the power terminal and the second terminal of the transistor.

18. The switching converter of claim 16, wherein the first variable resistor includes:
a resistor coupled between the power terminal and the set input;
a first transistor having a first terminal coupled to the power terminal, a second terminal, and a control terminal coupled to the output of the slew detector; and
a second transistor having a first terminal coupled to the second terminal of the first transistor, a second terminal coupled to the set input, and a control terminal coupled to the first latch output.

19. The switching converter of claim 16, wherein the second variable resistor includes:
a resistor coupled between the power terminal and the reset input;
a first transistor having a first terminal coupled to the power terminal, a second terminal, and a control terminal coupled to the output of the slew detector; and
a second transistor having a first terminal coupled to the second terminal of the first transistor, a second terminal coupled to the reset input, and a control terminal coupled to the second latch output.

20. The switching converter of claim 16, further comprising:
a pulse generator having a first pulse output and a second pulse output, the pulse generator configured to provide a first pulse at the first pulse output and provide a second pulse at the second pulse output;
a first transistor having a first terminal coupled to the set input, a second terminal coupled to a reference terminal, and a control terminal coupled to the second pulse output; and
a second transistor having a first terminal coupled to the reset input, a second terminal coupled to the reference terminal, and a control terminal coupled to the first pulse output.
